(19) United States
(12) Patent Application Publication
(10) Pub. No.: US 2002/0130390 A1
(43) Pub. Date: Sep. 19, 2002

(54) ESD protection circuit with very low input capacitance for high-frequency I/O ports

(76) Inventors: Ming-Dou Ker, Hsinchu (TW); Hun-Hsien Chang, Hsi-Chih City (TW); Wen-Tai Wang, Taipei (TW)

Correspondence Address: BIRCH STEWART KOLASCH & BIRCH, PO BOX 747, FALLS CHURCH, VA, 22040-0747, US

(21) Appl. No.: 09/944,171

(22) Filed: Sep. 4, 2001

(30) Foreign Application Priority Data
Mar. 13, 2001 (TW) 90105922

(51) Int. Cl. H01L 29/76

(52) U.S. Cl. 257/546; 257/372; 257/173; 257/355

(57) ABSTRACT

The present invention proposes an ESD protection circuit with low input capacitance, suitable for an I/O pad. The ESD protection circuit includes a plurality of diodes and a power-rail ESD clamp circuit between power lines. The diodes are stacked and coupled between a first power line and the I/O pad. The ESD protection circuit between power lines is coupled between the first power line and a second power line. During normal operation, the diodes are reverse-biased and the ESD protection circuit between power lines is turned off. When an ESD event between the power line and the I/O pad occurs, the diodes are forward-biased, and the ESD protection circuit between power lines is turned on to conduct ESD current. The equivalent input capacitance of the ESD protection circuit of the present invention is very small, making it particularly suitable for the I/O port of high-frequency or high-speed IC.

### BACKGROUND OF THE INVENTION

1. Field of the Invention

The present invention relates to an electrostatic discharge (ESD) protection circuit with low capacitance, in particular, to an ESD protection circuit suitable for high-frequency I/O ports.

2. Description of the Related Art

As the manufacturing process for integrated circuit (IC) improves, the gate oxide layer of metal-oxide-semiconductor transistors (MOS) becomes thinner and more easily damaged by unexpected stress. Thus, it has become more and more important to provide effective ESD protection circuit in I/O ports or between power supply lines to prevent internal elements from being damaged by ESD stress.

FIG. 1(a) is a conventional ESD protection circuit composed of two diodes, being put between an input/output (I/O) pad 10 and an internal circuit 12. P-type diode Dₚ₁ is connected between VDD and I/O pad 10, n-type diode Dₙ₁ is connected between VSS and I/O pad 10. FIG. 1(b) is an improved version of FIG. 1(a), being a two-stage ESD protection circuit. Primary ESD protection circuit 14 is composed of Dₚ₁ and Dₙ₁, while secondary ESD protection 16 is composed of Dₚ₂ and Dₙ₂. In general, the p-type diode in FIG. 1(a) or FIG. 1(b) has a PN junction formed by placing a p-type heavily doped area 20 in an n-type well 24, as shown in FIG. 2. The n-type diode in FIG. 1(a) or FIG. 1(b), in general, has a PN junction formed by placing a heavily doped n-type area 28 in a p-type well 22, as shown in FIG. 3. The N-type well 24 and the p-type well 22 are usually directly in contact with the p-type substrate 26.

There are four different pin combinations to verify the ESD level of an input (or output) pin of an IC, as the PS-, NS-, PD- and ND-modes ESD stresses shown in FIG. 4. They are:

(i)PS-mode ESD stress: a positive ESD pulse is applied to a tested IC pin with the VSS pin relatively grounded, while other non-tested pins are all floating;

(ii) NS-mode ESD stress: a negative ESD pulse is applied to a tested IC pin with the VSS pin relatively grounded, while other non-tested pins are floating;

(iii) PD-mode ESD stress: a positive ESD pulse is applied to a tested IC pin with the VDD pin relatively grounded, while other non-tested pins are floating; and

(iv) ND-mode ESD stress: a negative ESD pulse is applied to a tested IC pin with the VDD pin relatively grounded, while other non-tested pins are flowing.

The I/O pad 10 of FIG. 1(a) and FIG. 1(b) under these four different ESD-stress modes has a different ESD sustained voltage level. The ESD level of a pin is defined as the lowest voltage (in magnitude) that the pin can sustain. In PD mode (or NS mode), the D^{p1} (or Dₙ₁) is forward-biased to release ESD current. The forward bias voltage of the diode is about 0.8 V in the general CMOS manufacturing process. In PS (or ND) mode, Dₙ₁ (or Dₚ₁) is reverse-biased to break down, releasing ESD current. During breakdown, the voltage across of the diode is about 10 V in a 0.35 μm CMOS manufacturing process. The generated power of the diode is I_{diode}*V_{diode}, in which I_{diode} is the current flowing through the diode and V_{diode} is the voltage across the diode. From above, the generated power of the diode during breakdown will be much larger than the generated power during forward bias. Therefore, the design of the Dₚ₁ and Dₙ₁ emphasizes how to make Dₚ₁ and Dₙ₁ release ESD current effectively during ND- and PS-mode ESD stress without burning themselves out.

In order to reach the commercial requirement of +/−2000 V for human body model (HBM) in the commercial specification, Dₚ₁ and D₁ are generally designed as large-sized elements. The device width may be as large as several hundred micrometers. Large elements have a large volume to efficiently dissipate the heat generated during the release of ESD stress, thus preventing burnout of Dₚ₁ and Dₙ₁ during ESD events.

However, large elements will cause large loading to the I/O port. FIG. 5 is the equivalent circuit of FIG. 1(a), showing parasitic capacitors therein. In view of small signal circuit analysis, the input equivalent capacitance Cᵢₙₚᵤₜ seen from I/O pad 10 of FIG. 1(a) is approximately equal to C_{pad}+Cⱼₚ+Cⱼₙ; in which, C_{pad} is the parasitic capacitance formed by a large metal plate constituting a bonding pad and the surrounding conductor, Cⱼₚ is the parasitic capacitance of PN junction of Dp1 (as shown in FIG. 2), Cⱼₙ is the parasitic capacitance of the PN junction of Dₙ₁ (as shown in FIG. 3). In general, a bonding pad with a 100 μm*100 μm metal plate has approximately 0.5 pF parasitic capacitance. The parasitic capacitance of Dp1 (or Dn1) with an element width of few hundred micrometers is about 2˜4 pF. Roughly speaking, the input equivalent capacitance Cᵢₙₚᵤₜ is about 5 pF, where most of it is contributed by Dₚ₁ or Dₙ₁. Such high input capacitance will lower the response speed of the I/O port at high frequencies. For high-frequency IC or high-speed IC, in particular, the smaller the loading of the I/O port the better. Thus, circuit designs as shown in FIG. 1(a) or FIG. 1(b) are not suitable for high-frequency or high-speed ICs.

In addition, for the I/O port with current as the input signal or high-frequency I/O port, an additional resistor, as R in FIG. 1(a) and FIG. 1(b), will cause non-linear frequency response and introduce thermal noise to distort the input signal. Such distortion is not allowed. Under this limit, conventional ESD protection circuits of FIG. 1(a) and FIG. 1(b) are not suitable for high-frequency IC application. Therefore, it is a challenge for ESD protection circuit designers to design an ESD protection circuit capable of high-speed IC and bearing high ESD stress.

### SUMMARY OF THE INVENTION

The main object of the present invention is to provide an ESD protection circuit with high ESD tolerance level and small capacitance, especially suitable for high frequency IC I/O ports.

According to the above object, the present invention proposes an ESD protection circuit with low input capacitance loading, suitable for an I/O pad. The ESD protection circuit contains a plurality of diodes and a power-rail ESD clamp circuit. The diodes are stacked between a first power line and the I/O pad. The power-rail ESD clamp circuit is coupled between the first power line and a second power line. During normal power operation, the diodes are reverse-biased and the power-rail ESD clamp circuit is turned off. When an ESD event occurs between the second power line and the I/O pad, the power-rail ESD clamp circuit is turned on to conduct ESD current through the forward-biased diodes.

Each diode has a PN junction formed between a first well of a second conductivity type and a doped region of a first conductivity type therein. A deep well of a first conductivity is located under the first well to isolate the first well from a substrate of the second conductivity.

Due to the stack structure, the equivalent capacitance of the stack diodes will be smaller than the parasitic capacitance of a single diode. Hence one advantage of the present invention is to effectively reduce a large amount of input capacitance loading.

Another advantage of the present invention is that the diodes are forward-biased to release ESD stress, unlike the prior art, which is reverse-biased to release ESD stress. Thus, each diode can be constructed as a smaller sized element. The chip area required by the I/O port can be reduced and, as a result, the input capacitance is further reduced.

The present invention also provides a power-rail ESD clamp circuit, suitable for an integrated circuit, coupled between two power lines. The ESD clamp circuit between power lines includes a substrate-triggered NMOS and an ESD detection circuit. The NMOS includes a gate, two source/drains and a substrate. The two source/drains are coupled to the two power lines respectively. When an ESD event is detected, the ESD detection circuit provides a bias current to the substrate of the NMOS, and a bias voltage to the gate of the NMOS element, to trigger the NMOS and release ESD stress.

Because the gate and the base of the NMOS element are simultaneously biased during the ESD event, the triggering speed can be greatly increased. Thus, the ESD current between the power lines can be released rapidly to protect the internal circuit of the integrated circuit.

### BRIEF DESCRIPTION OF THE DRAWINGS

The present invention can be more fully understood by reading the subsequent detailed description in conjunction with the examples and references made to the accompanying drawings, wherein:

FIG. 1(a) shows a conventional ESD protection circuit consisted of two diodes;

FIG. 1(b) shows a two-stage ESD protection circuit in the prior art;

FIG. 2 illustrates the structural cross-sectional view of the conventional p-type diode;

FIG. 3 illustrates the structural cross-sectional view of the conventional n-type diode;

FIG. 4 introduces the four different ESD stress modes;

FIG. 5 is the circuit diagram in FIG. 1(a) with its parasitic capacitors;

FIG. 6 is an ESD protection circuit according to the present invention;

FIGS. 7 to 10 illustrate ESD current paths in the ESD protection circuit under the four different ESD stress modes;

FIG. 11 is an n-type diode of the present invention and its representative symbols;

FIG. 12 is the structural cross-sectional view of the M_{ESD} element in FIG. 6 and the symbol schematic view;

FIG. 13 is the improved ESD protection circuit of FIG. 6 according to the invention;

FIG. 14 is an ESD protection circuit with three diodes stacked between a power line and a pad according to the present invention;

FIG. 15 represents the HSPICE simulation result of the input equivalent capacitance of FIG. 5, FIG. 6 and FIG. 14;

FIG. 16 illustrates an NMOS with deep N well structure and the parasitic n-type diode therein applied in the present invention;

FIG. 17 illustrates a PMOS and the parasitic p-type diode therein applied in the present invention; and

FIGS. 18 to 25 are 8 embodiments utilizing the diodes with NMOS or PMOS structures according to the present invention.

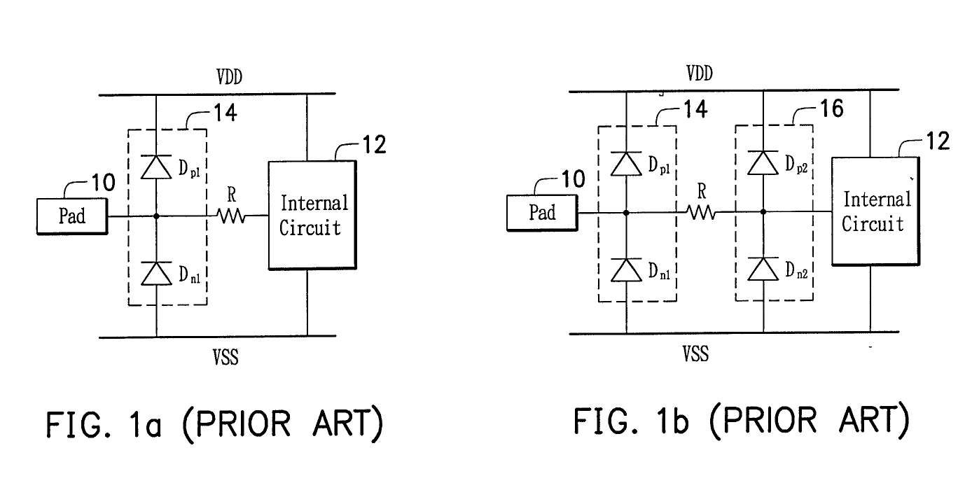

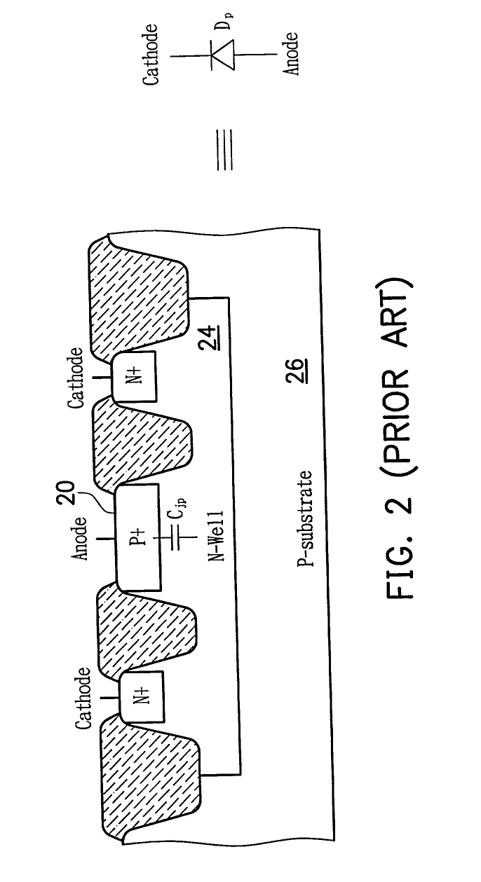

### DETAILED DESCRIPTION OF THE PREFERRED EMBODIMENT

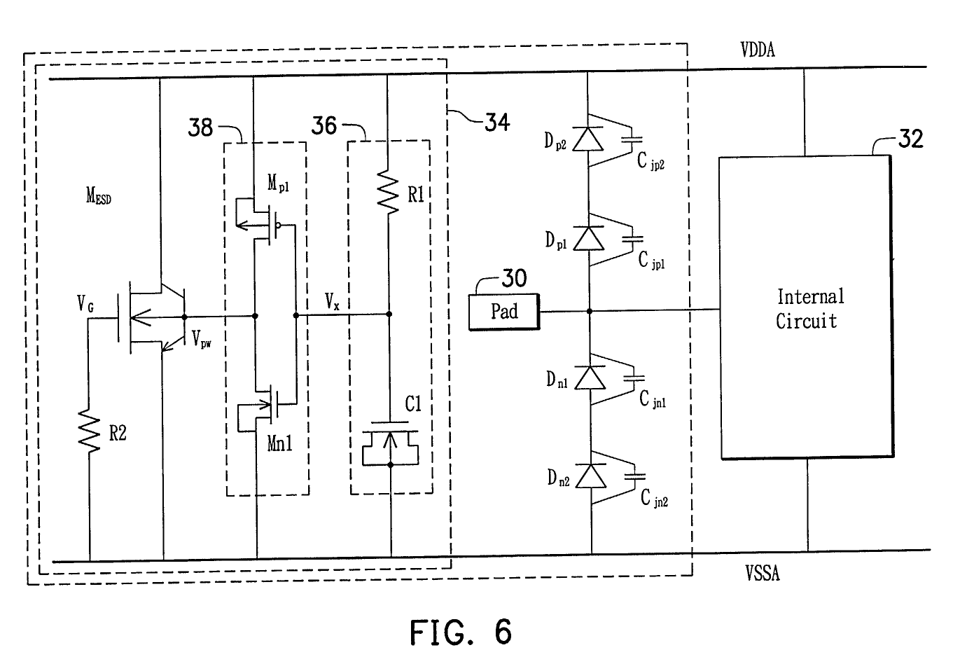

In order to reduce the input equivalent capacitance, the present invention proposes a stack structure of diodes as ESD protection circuit, as shown in FIG. 6. Two n-type diodes (Dₙ₁ and Dₙ₂) stack between a pad 30 and a power line VSSA. Two p-type diodes (Dₚ₁ and Dₚ₂) stack between the pad 30 and VDDA. During the normal operation of an integrated circuit, Dₚ₁, Dₚ₂, Dₙ₁, Dₙ₂ are reverse-biased but not breakdown, such that electrical signals at the pad 30 can be transmitted to the internal circuit 32. The values of the parasitic capacitance of the diodes are represented by Cⱼₙ₁, Cⱼₙ₂, Cⱼₚ₁ and Cⱼₚ₂, as shown in FIG. 6. Because of the stack structure, the equivalent capacitance input can be effectively reduced. For example, set Cⱼₙ₁=Cⱼₙ₂=Cⱼₙ and C_{jp1=C}ⱼₚ₂=Cⱼₚ, the input equivalent capacitance Cᵢₙₚᵤₜ becomes

Cᵢₙₚᵤₜ=C_{pad+}(Cⱼₙ+Cⱼₚ)/2

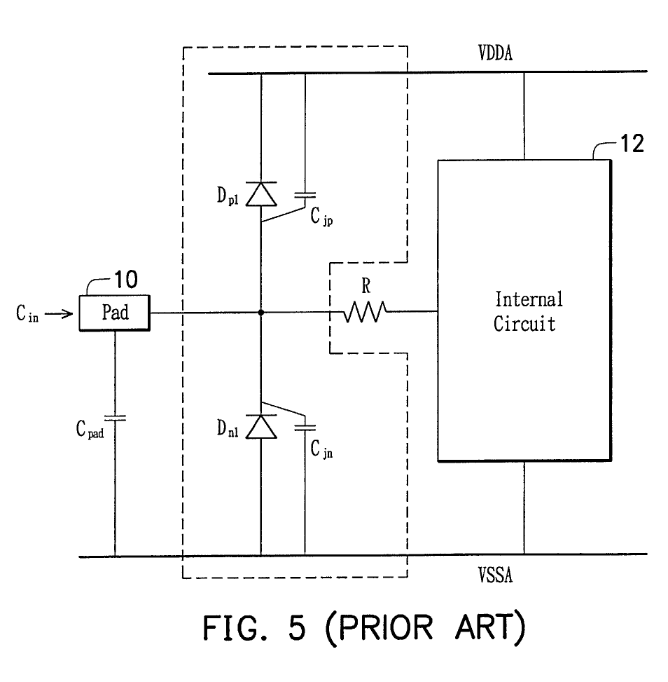

In comparison to the conventional ESD protection circuit in FIG. 5, the capacitance (or loading) generated by ESD protection circuit of FIG. 6 is only halved. Thus, the frequency response of the input port can be effectively improved.

However, the breakdown voltage of the stacked diodes will be two times the breakdown voltage of a single diode. The higher breakdown voltage means that the internal circuit 32 is easier to be damaged in an ESD event (for example, ND or PS modes). In order to assure the ESD robustness of the I/O port, there is a VDDA-to-VSSA ESD clamp circuit 34 coupled between VDDA and VSSA, as shown in FIG. 6. VDDA-to-VSSA ESD clamp circuit 34 consists of a RC delay circuit 36 formed by resistor R1 and capacitance C1 in series, an inverter 38 formed by Mₚ₁ and Mₙ₁, and a substrate-triggered NMOS M_{ESD}. RC delay circuit 34 is used to detect occurrence of the ESD event, inverter 38 provides a bias current to trigger npn bipolar junction transistor parasitizing in M_{ESD}, thereby releasing ESD current. The gate of M_{ESD} is coupled to VSSA through resistor R2 to assure M_{ESD} is turned off during non-ESD event.

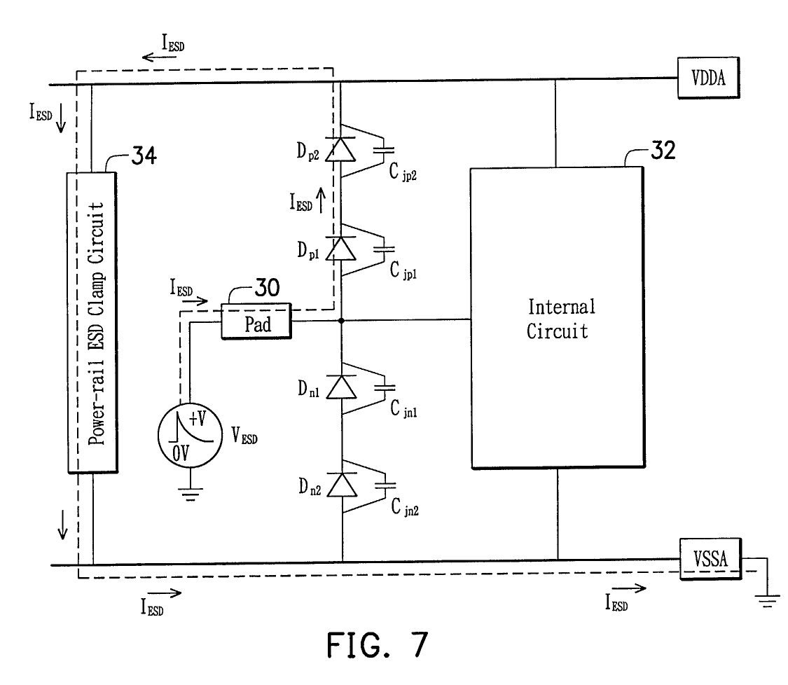

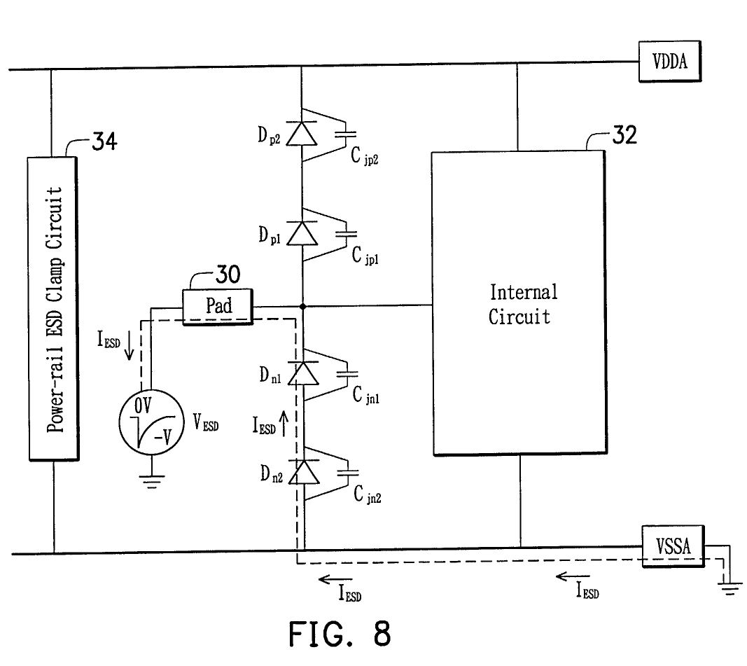

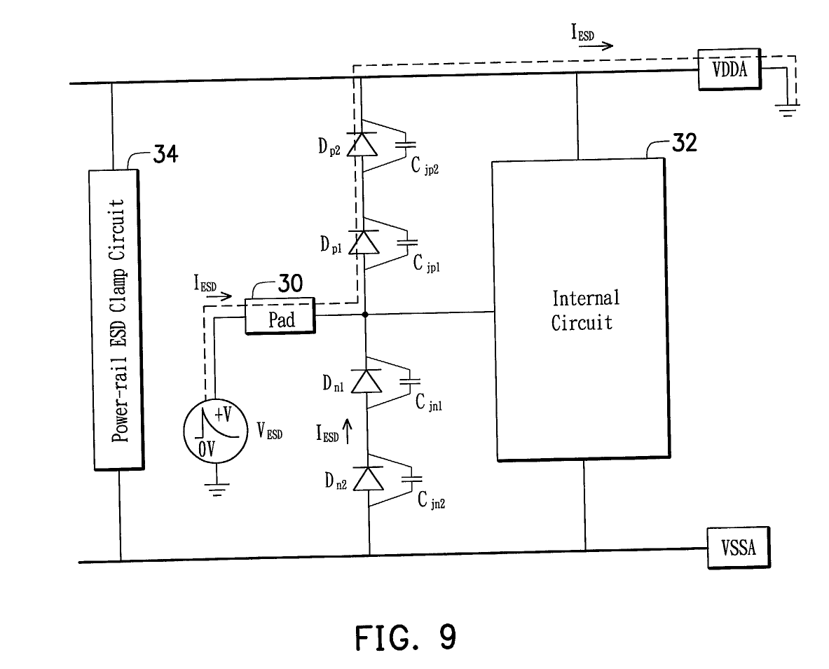

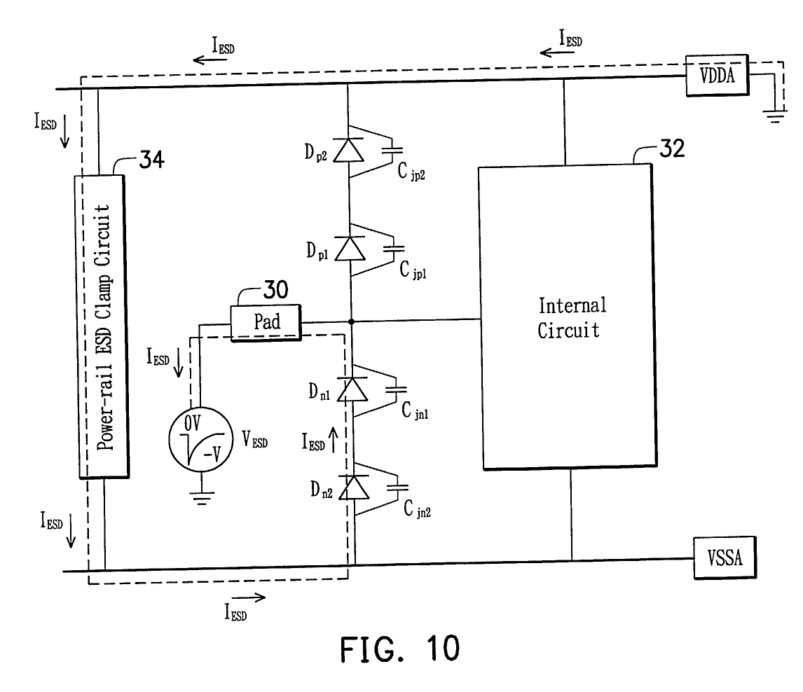

FIGS. 7 to 10 show the ESD protection circuits of the present invention together with the corresponding ESD current paths during the four ESD stress modes. FIG. 7 illustrates the ESD current path under PS mode. ESD current I_{ESD} from pad 30, through forward-biased Dₚ₁ and Dₚ₂, conducts into VDDA. Then, VDDA-to-VSSA ESD clamp circuit 34 is turned on so that I_{ESD} flows to VSSA from VDDA, and flows out of IC from grounded VSSA. FIG. 8 illustrates the ESD current path under NS mode ESD stress. I_{ESD}, through forward-biased Dₙ₁ and Dₙ₂, flows from VSSA into pad 30. FIG. 9 shows the condition under PD mode, I_{ESD} flows from pad 30, through forward-biased Dₚ₁ and Dₚ₂, into VDDA. FIG. 10 shows the condition under ND mode, ESD clamping circuit 34 between power lines is triggered to conduct current because of the ESD stress so that I_{ESD} flows from VDDA to VSSA, then through forward-biased Dₙ₁ and Dₙ₂, I_{ESD} flows from VSSA into pad 30.

From the above analysis, in an ESD event, stacked diodes always conduct ESD current under forward-bias conditions. The power generated for the diode under forward-bias is smaller than that for the diode during breakdown. Thus, in comparison to the conventional ESD protection circuit utilizing only a single diode between a pad and a power line, the ESD robustness of the ESD protection circuit of the present invention can be greatly increased.

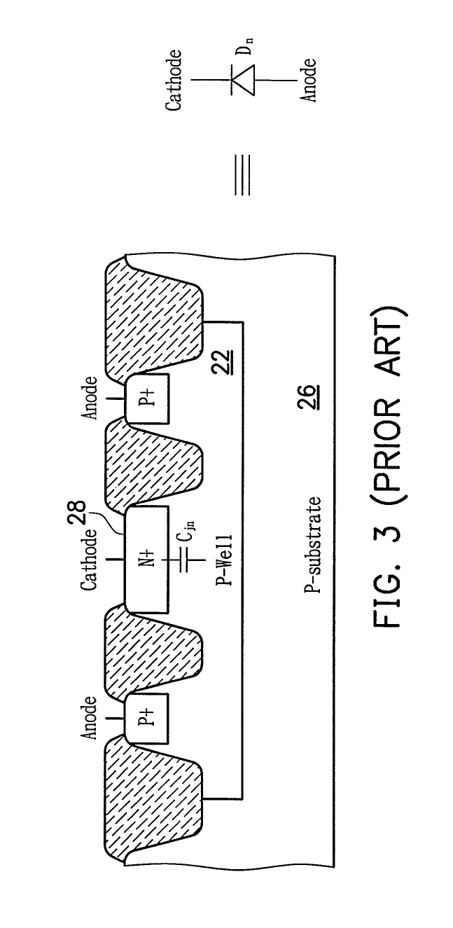

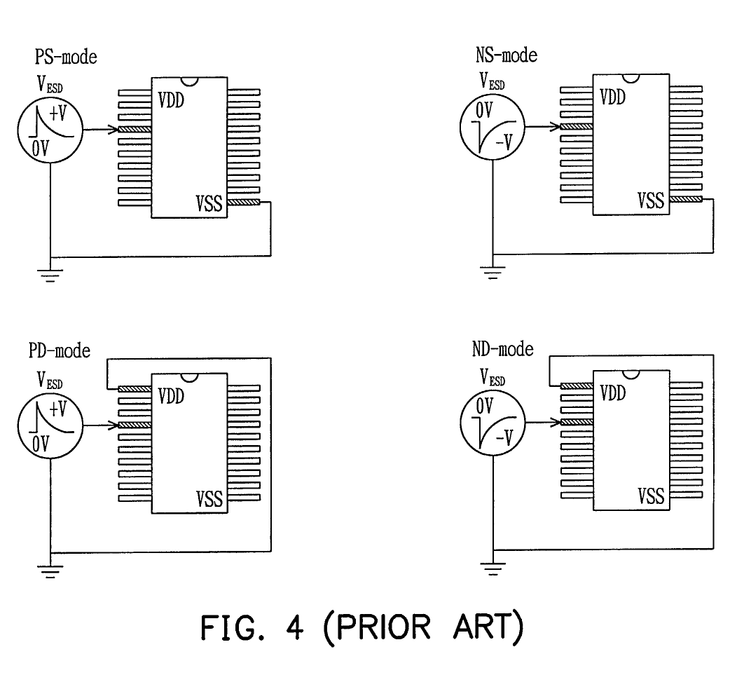

However, the conventional n-type diode in FIG. 3 has a common p-type substrate 26. Thus, such an n-type diode cannot be stacked in series, to meet the connection requirement for Dn1 and Dn2 as shown in FIG. 6.

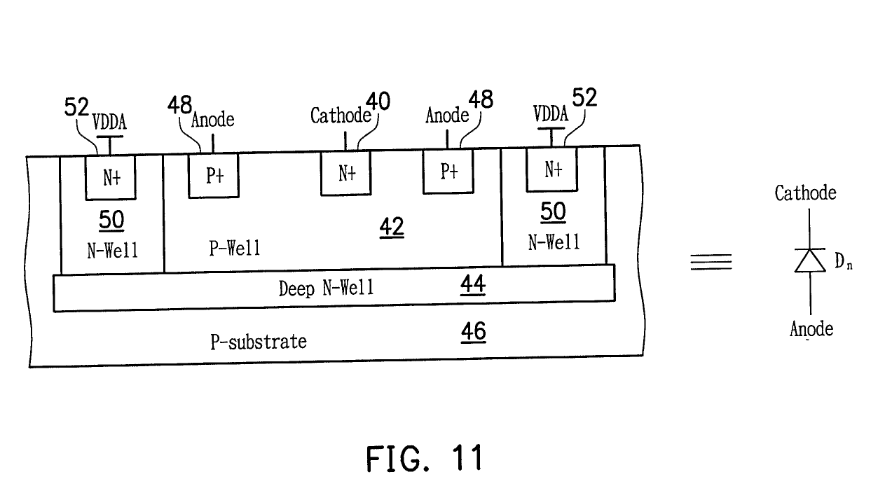

In order to achieve the configuration of the stacked diode circuit in FIG. 6, the present invention proposes a novel n-type diode structure, as shown in FIG. 11. FIG. 11 shows the novel n-type diode structure and its symbols used later in this specification. The n-type diode structure used in the present invention contains an N+ doped region 40 in a p-type well 42. N+ doped region 40 is the cathode of the n-type diode. P-type well 42 and the P+ doped region 48 thereon is the anode of the n-type diode. The entire n-type diode is surrounded by an n-type well 50 and the deep n-type well 44, so that p-type well 42 and p-type substrate 46 are separated from each other. The n-type well 50 and the deep n-type well 44 are coupled to VDDA through N+ doped region 52. Deep n-type well structures are commonly used in radio frequency IC or dynamic random access memory (DRAM) IC, and usually separate a common p-type substrate from p-type wells in which NMOS is placed, preventing noise from migrating through the common p-type substrate. The stacked diode circuit in FIG. 6 can be realized using the n-type diode in the isolated p-type well.

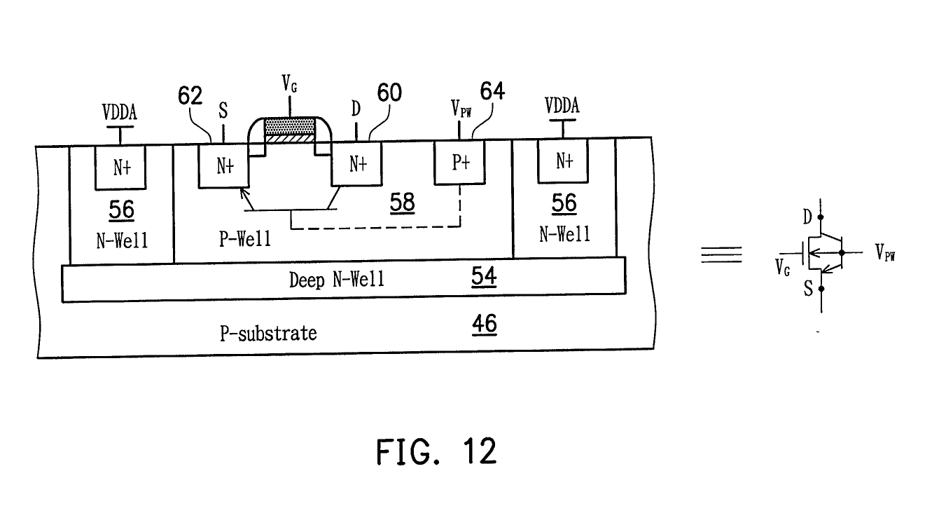

The substrate-triggered NMOS M_{ESD} in FIG. 6 can also use a deep n-type well to isolate the p-type well and the common p-type substrate 46. FIG. 12 is the cross-sectional view of the M_{ESD} in FIG. 6 and its symbol schematic view. The n-type well 56 and the deep n-type well 54 separate the p-type well 58 from the common p-type substrate 46. M_{ESD} forms in the isolated p-type well 58. The source and drain of the M_{ESD} are N+ doped regions 62 and 60 respectively, its substrate (node) is p-type well 58, as a contact point through P+ doped area 64. In this way, the output terminal of the inverter 38 in FIG. 6 can control the turning on and off of parasitic npn transistor (formed by the N+ doped region 60, the p-type well 58 and the N+ doped region 62) by biasing the p-type well 58. Because the isolation of the deep n-type well, the triggered current from the inverter 38 will not be branched to p-type substrate 46 and efficiently drive M_{ESD}, such that the turn-on rate of M_{ESD} can be increased.

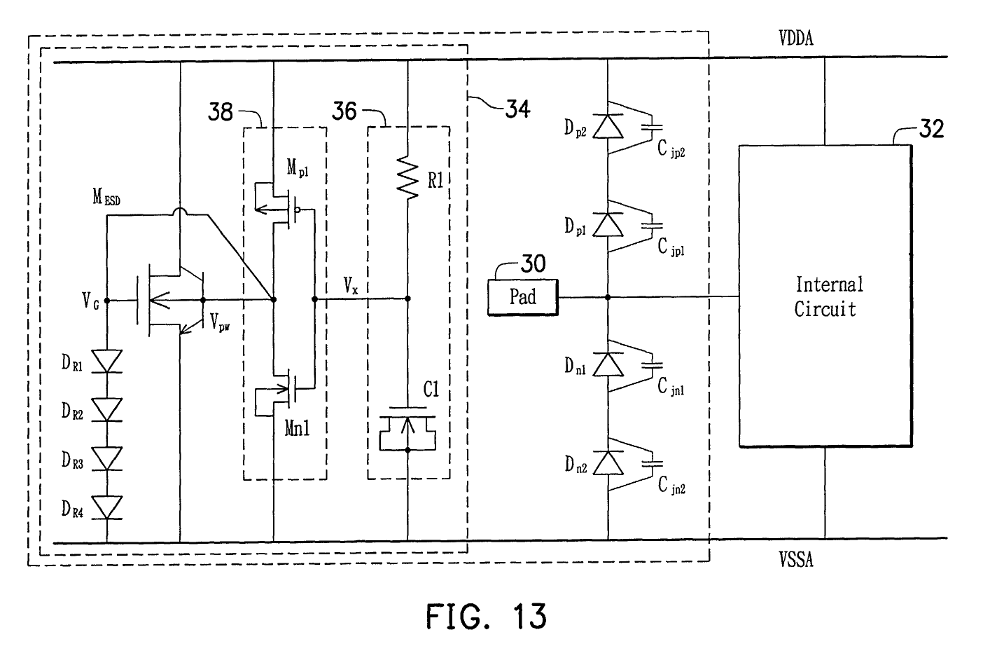

FIG. 13 is an improved ESD protection circuit of FIG. 6. In order to increase the turn-on rate of the VDDA-to-VSSA ESD clamp circuit 34, a bias voltage can be applied to the gate of M_{ESD}. In FIG. 13, inverter 38 not only provides the bias current into the substrate of the M_{ESD}, but also provides the bias voltage on the gate of M_{ESD}. In order to prevent the bias voltage on the gate from being overlarge, possibly damaging M_{ESD} a plurality of diodes D_{R1} . . . D_{R4} are stacked between the MESD gate and VSSA. D_{R1} . . . D_{R4} clamp the largest voltage at the M_{ESD} gate. When an ESD event occurs, inverter 38 provides current to the base of the parasitic npn bipolar junction transistor, and at the same time pulls up the M_{ESD} gate to the clamp voltage limited by D_{R1} . . . D_{R4}. The number of diodes stacked between the M_{ESD} gate and VSSA can be different depending upon the different applications, and is not limited to four. Another way to prevent the voltage at the gate from getting too large is to place a Zener diode (not shown) coupled between the gate and VSSA, to replace the stacked plurality of the diodes D_{R1} . . . D_{R4}. When an ESD event occurs, the Zener diode is reverse-biased to enter breakdown condition, the fixed breakdown voltage of the Zener diode limits the amplitude of the bias voltage at the gate, thereby M_{ESD} being protected.

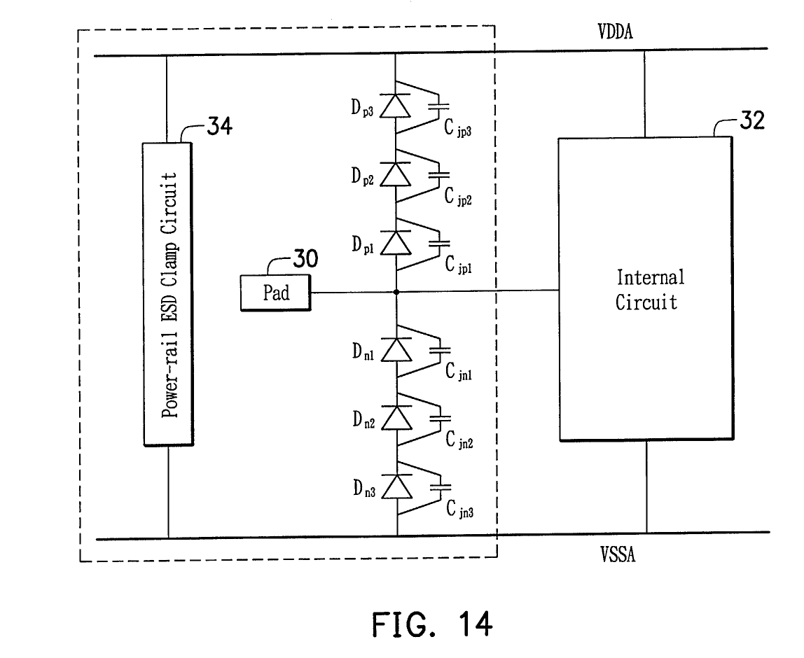

Once the turn-on rate of VDDA-to-VSSA ESD detection circuit 34 is sped up, the number of the diodes stacked between the power line (VDDA or VSSA) and the pad 30 can be further increased to obtain a smaller input equivalent capacitance. FIG. 14 is an ESD protection circuit diagram with three diodes stacked between power lines and the pad according to the present invention. Three n-type diodes (Dₙ₁, Dₙ₂, and Dₙ₃) stacked between the pad 30 and VSSA; three p-type diodes (Dₚ₁, Dₚ₂, and Dₚ₃) stacked between the pad 30 and VDDA. If every N type diode has the same parasitic capacitance Cⱼₙ, and every p-type diode has the same parasitic capacitance Cⱼₚ, the input equivalent capacitance in FIG. 14 is

Cᵢₙₚᵤₜ=C_{pad}+(Cⱼₚ+Cⱼₙ)/3

Hence, when the number of the stacked diodes increases, input equivalent capacitance lowers. Lower input equivalent capacitance is required by both the high speed IC and the high frequency IC.

The main spirit of the present invention is to lower the effective input capacitance by stacking diodes, and, by employing a VDDA-to-VSSA ESD clamp circuit, solve the high breakdown voltage problem induced by the stacked diodes.

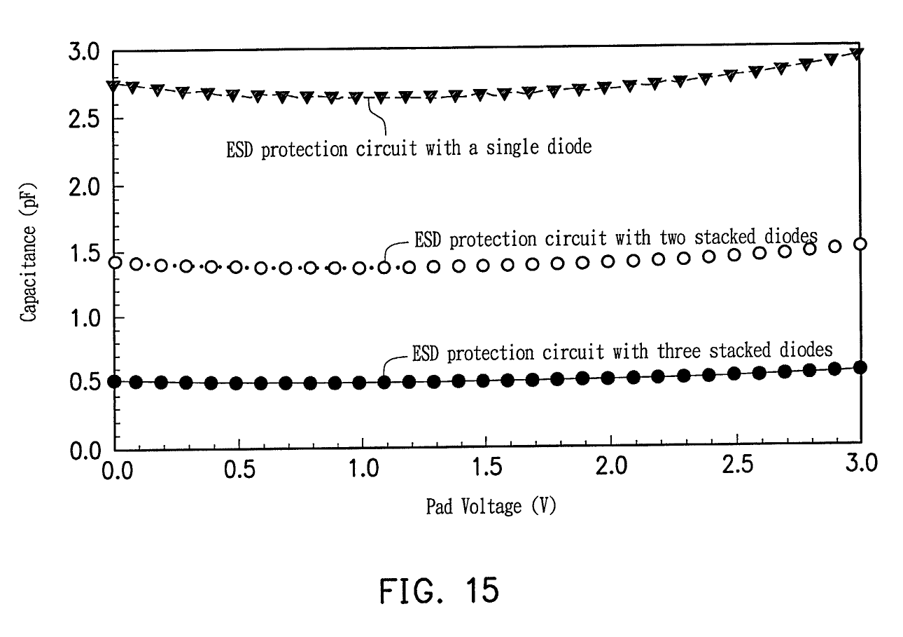

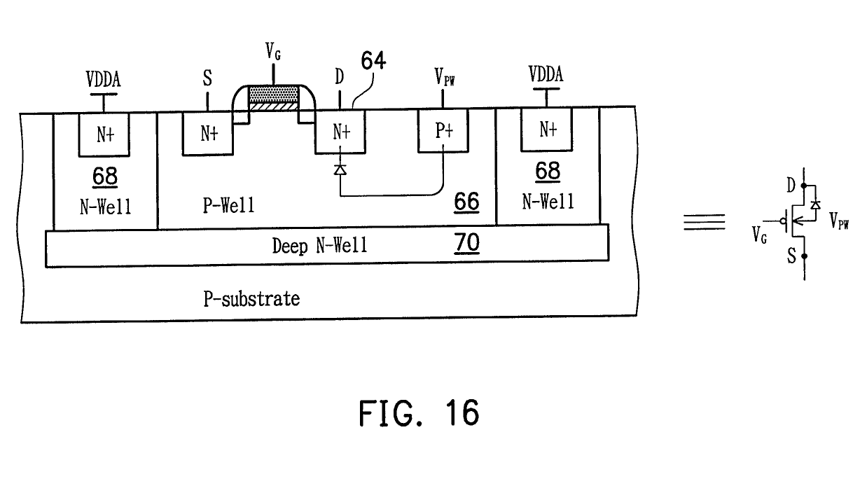

FIG. 15 is the HSPICE simulation result of the input capacitance in FIGS. 5, 6 and 14; wherein VDDA is 3V, VSSA is ground. Input equivalent capacitance in FIG. 16 is almost constant and does not change greatly as voltage of the junction pad varies. From FIG. 15, the input equivalent capacitance of the ESD protection circuit of a single diode (as shown in FIG. 5) is about 3 pF. The input equivalent capacitance of the ESD protection circuit of two stacked diodes (as shown in FIG. 6) is about 1.5 pF. The input equivalent capacitance of the ESD protection circuit of three stacked diodes (as shown in FIG. 14) is lowered to about 0.5 pF. Hence, the effect of increasing the number of the stacked diodes to lower input equivalent capacitance can be seen.

The diodes of the present invention need only be stackable; they are not limited to the structure shown in FIG. 11. For example, some of the diodes that can be used include p-type diodes, n-type diodes, NMOS diodes, PMOS diodes, the n-type diodes that parasitize in the drain of NMOS, or the p-type diodes that parasitize in the drain of PMOS. NMOS (or PMOS) diode refers to an NMOS (or PMOS) whose gate and source are connected together as an anode (or cathode) and its drain is used as a cathode (or anode). The different diodes can be swapped with one another.

FIG. 16 is a schematic of the n-type diode that parasitizes around a drain of an NMOS and can be used in the present invention. The drain of the NMOS in FIG. 16 is N+ doped region 64. The bulk of the NMOS is a p-type well 66, which is separated from other p-type wells (not shown) by an n-type well 68 and a deep n-type well 70. The PN junction between the drain and the bulk is also an n-type diode, which can be employed in the present invention. The gate of NMOS can be coupled to the power line VSSA in the circuit so that NMOS is turned-off during normal operation; or is coupled to its own source, to form an additional NMOS diode. Both can be used in the present invention.

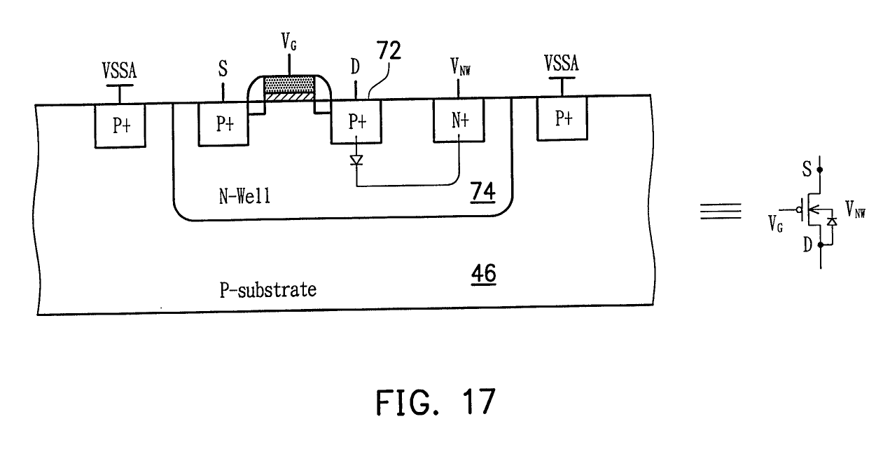

FIG. 17 is a schematic of the p-type diode that parasitizes around a drain of a PMOS and can be used in the present invention. The drain of the PMOS is a P+ doped region 72. The bulk of the PMOS is an n-type well 74. The n-type well 74 and other n-type wells (not shown) are separated by the p-type substrate 46. The PN junction between the drain and the bulk of the PMOS is also a p-type diode. The gate of the PMOS can be coupled to the highest voltage VDDA in the circuit so that PMOS is at turn-off state during normal operation; or is coupled to the source thereof to form an additional PMOS diode. Both can be used in the present invention.

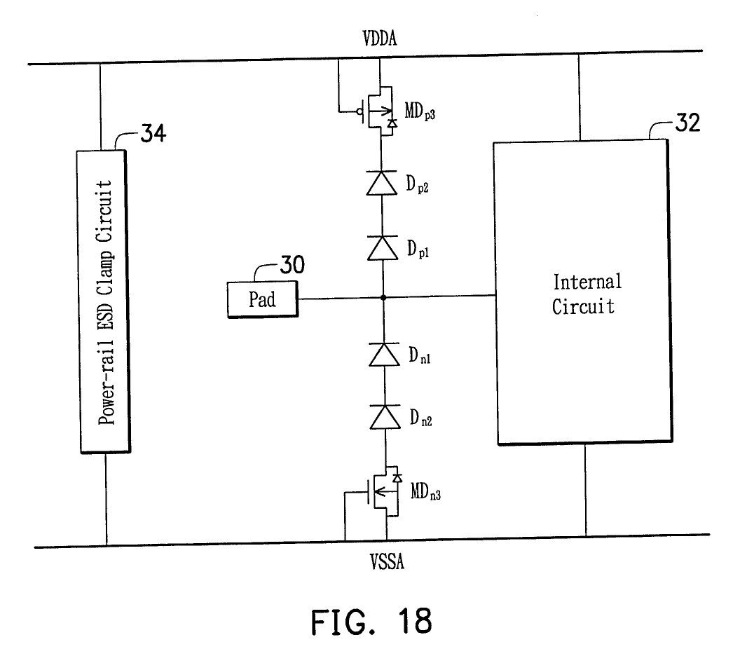

FIGS. 18 to 25 are ESD protection circuits utilizing the junction diodes between the drain and the bulk of the NMOS and PMOS according to the present invention. In FIG. 18, the connection of the MDₚ₃ represents the parallel combination of two types of diodes. One is a PMOS diode (because the gate is coupled to the source), the other is p-type diode (because the bulk is coupled to the source), so the current conductivity can be greatly increased. In the same way, the connection of the MD₃ represents the parallel combination of two types of the diodes. One is an NMOS diode (because the gate is coupled to the source); the other is an n-type diode (because the bulk is coupled to the source).

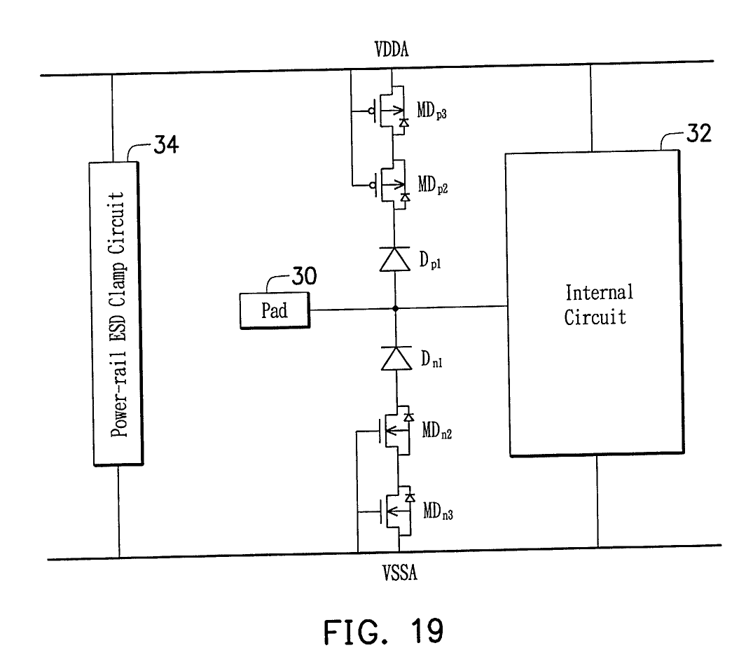

FIG. 19 uses two PMOS (MDₚ₂ and MDₚ₃) and two NMOS (MDₙ₂ and MDₙ₃) as diodes. The gates of MDₚ₂ and MDₚ₃ are connected to VDDA. The gates of MDₙ₂ and MDₙ₃ are connected to VSSA.

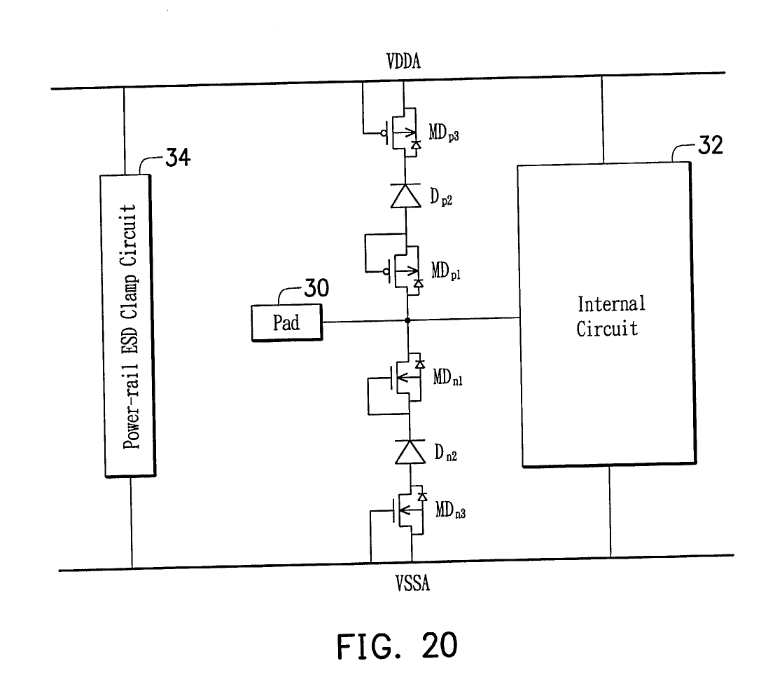

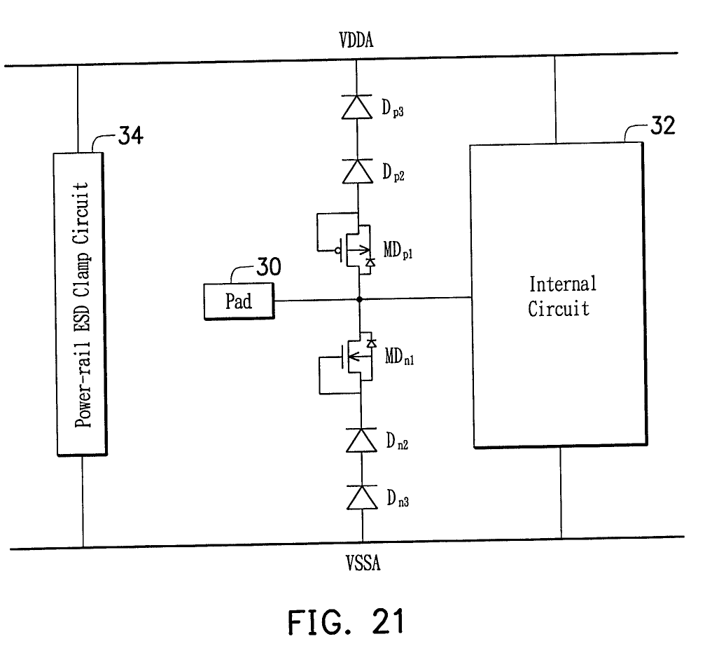

The order of the stacked diode can be changed as wished. In FIGS. 18 and 19, the NMOS and PMOS diodes are placed closest to the power lines (VDDA or VSSA). FIG. 20 and 21 are embodiments of two different orders, the gate of MDₚ₁ wherein is connected to its own source, but can also be connected to VDDA. The gate of MDₙ₁ is connected to its own source, but can also be connected to VSSA.

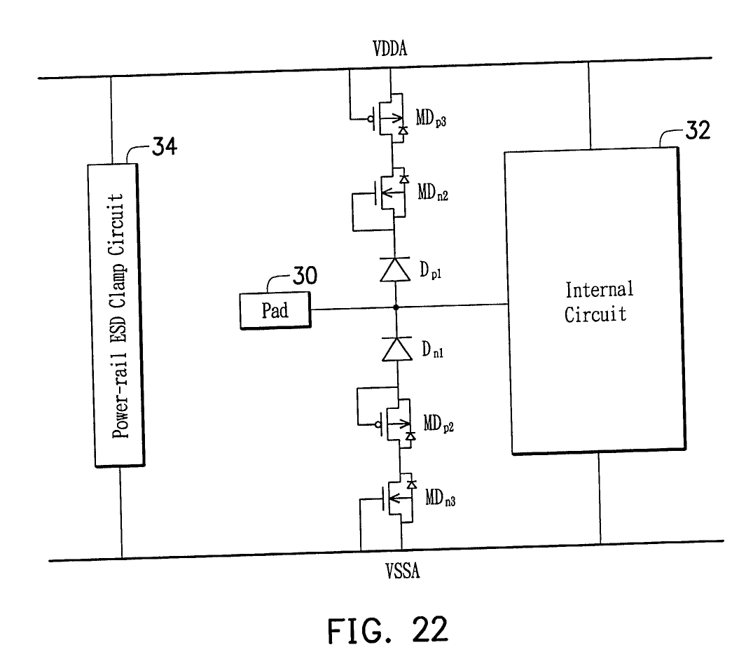

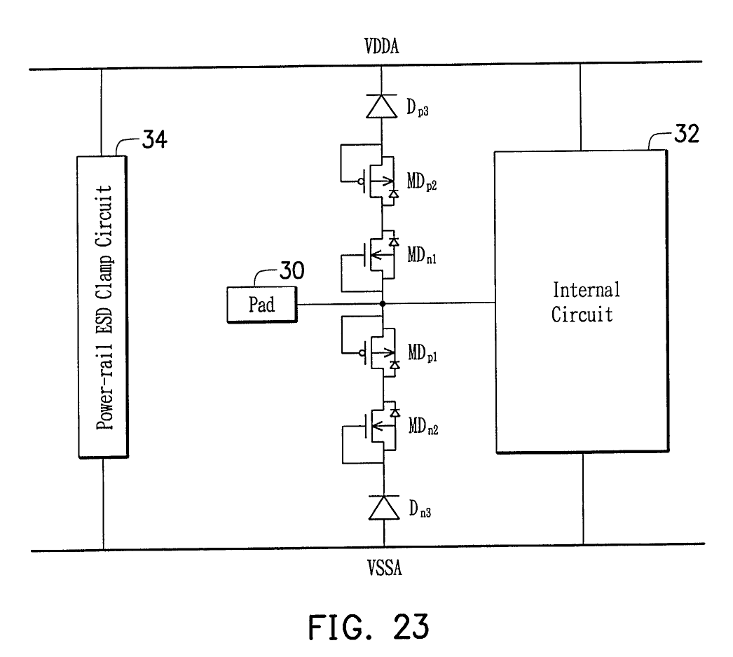

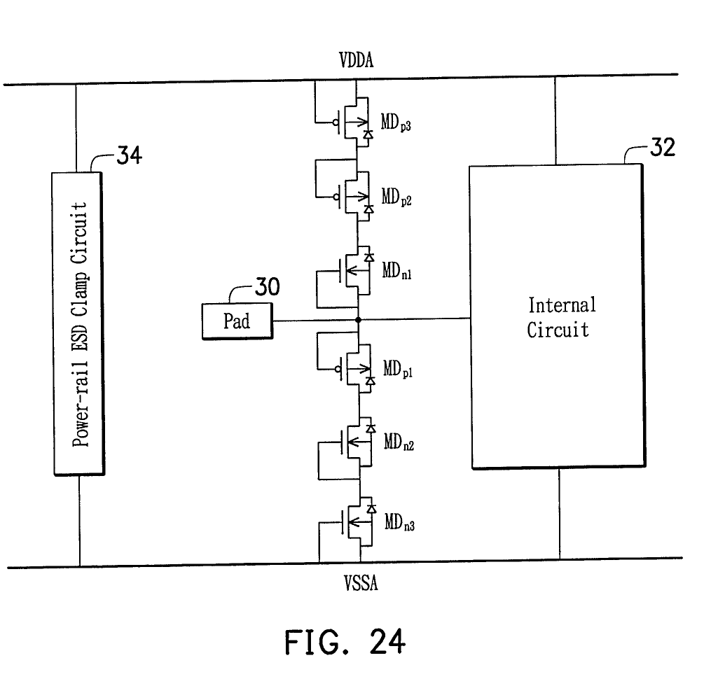

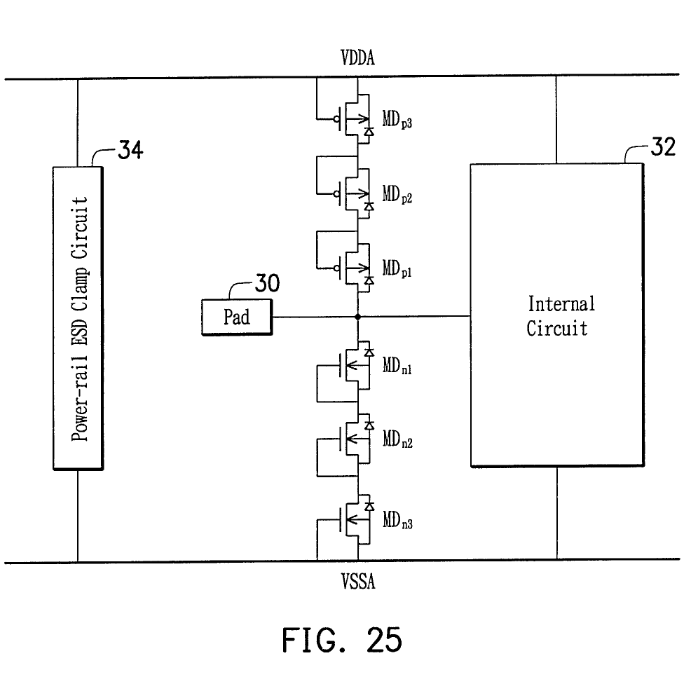

FIG. 22 and 23 are schematics of two ESD protection circuits formed by stacking three types of diodes, wherein the types of diodes stacked between VDDA and I/O pad can include a general n-type or p-type diode, a diode generated by NMOS and a diode generated by PMOS. The stacked diode circuit in the ESD protection circuit of the present invention can completely use diodes generated by PMOS or NMOS, as shown in FIG. 24 and 25.

In comparison to the prior art of ESD protection circuit, where a single diode is set between a pad and a power line, there is a plurality of diodes stacked between a power line and a pad in the present invention. The object of greatly reducing input equivalent capacitance is achieved. On the other hand, the ESD protection circuit between the power lines in the present invention solves the problem of lowered ESD robustness due to the stacked diodes. Hence, the ESD protection circuit of the present invention is particularly suitable in the I/O port of a high frequency or high speed IC.

While the invention has been described by way of examples and in terms of the preferred embodiments, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An electrostatic discharge (ESD) protection circuit with low input capacitance, suitable for an I/O pad, comprising a plurality of diodes, stacked and coupled between a first power line and the I/O pad, wherein during normal operation, the diodes are reverse-biased, and, when an ESD event occurs between a second power line and the I/O pad, the diodes are forward-biased to conduct ESD current.

2. The ESD protection circuit as claimed in claim 1, wherein each diode is a PN junction diode formed by placing a doped area of a first conductivity type in a first well of a second conductivity type, a deep well of the first conductivity type formed under the first well to isolate the first well from a substrate of the second conductivity type.

3. The ESD protection circuit as claimed in claim 2, wherein the first well is surrounded by a second well of the first conductivity type.

4. The ESD protection circuit as claimed in claim 2, wherein the first conductivity type is N type, and the second conductivity type is P type.

5. The ESD protection circuit as claimed in claim 1, wherein the ESD protection circuit further includes a power-rail ESD clamp circuit, set between a first power line and a second power line, the power-rail ESD clamp circuit being turned on to conduct ESD current when an ESD event occurs.

6. The ESD protection circuit as claimed in claim 5, wherein the power-rail ESD clamp circuit includes a substrate-triggered MOS of the first conductivity type, the substrate-triggered MOS including two source/drains and a substrate, the two source/drains coupled to the first power line and the second power line respectively, the substrate node biased with suitable current to trigger a bipolar junction transistor parasitizing in the substrate-triggered MOS, and conducting ESD current when an ESD event occurs.

7. The ESD protection circuit as claimed in claim 6, wherein the substrate-triggered MOS includes a gate applied with a first bias voltage to keep the substrate-triggered MOS off during normal operations.

8. The ESD protection circuit as claimed in claim 6, wherein the gate is applied with a second bias voltage to speed up the turn-on rate of the substrate-triggered MOS when an ESD event occurs.

9. The ESD protection circuit as claimed in claim 6, wherein the substrate-triggered MOS is formed in a first well of a second conductivity type, a deep well of a first conductivity type being formed under the first well to isolate the first well from a substrate of the second conductivity type.

10. The ESD protection circuit as claimed in claim 9, wherein the first well is surrounded by a second well of the first conductivity type.

11. The ESD protection circuit as claimed in claim 5, wherein the power-rail ESD clamp circuit includes an ESD detection circuit to detect the occurrence of the ESD event.

12. The ESD protection circuit as claimed in claim 1, wherein one of the diodes is a MOS diode with a gate coupled to a source/drain of the MOS diode.

13. The ESD protection circuit as claimed in claim 1, wherein the diode includes a PN junction diode formed by a PN junction between a source/drain and a substrate of a MOS.

14. The ESD protection circuit as claimed in claim 13, wherein the gate of said MOS is coupled to the first power line.

15. The ESD protection circuit as claimed in claim 13, wherein the gate of said MOS is coupled to another source/drain of the MOS.

16. The ESD protection circuit as claimed in claim 13, wherein the MOS is PMOS.

17. The ESD protection circuit as claimed in claim 13, wherein the MOS is NMOS.

18. A power-rail ESD clamp circuit, suitable for an integrated circuit, coupled between two power lines, comprising:
a substrate-triggered MOS, including:
a gate;
two source/drains, respectively coupled to two power lines; and
a substrate; and
an ESD detection circuit, providing a bias current to the substrate of the MOS, and a bias voltage to the gate of the MOS element to trigger the MOS and conduct ESD current when an ESD event occurs.

19. The power-rail ESD clamp circuit as claimed in claim 18, wherein the power-rail ESD clamp circuit further comprises a voltage clamp circuit coupled between the gate and one of the two power lines to limit the bias voltage.

20. The power-rail ESD clamp circuit as claimed in claim 19, wherein the voltage clamp circuit is formed by one diode forward-biased when the ESD event occurs.

21. The power-rail ESD clamp circuit as claimed in claim 19, wherein the voltage clamp circuit is formed by a plurality of stacked diodes forward-biased when the ESD event occurs.

22. The power-rail ESD clamp circuit as claimed in claim 19, wherein the voltage clamp circuit is formed by a Zener diode reverse-biased to clamp the bias voltage at a breakdown voltage when ESD event occurs.

23. The power-rail ESD clamp circuit as claimed in claim 18, wherein one of the two power lines is a high voltage power line, the other is a low voltage power line, and the substrate-triggered MOS is an NMOS.

24. The power-rail ESD clamp circuit as claimed in claim 18, wherein said ESD detection circuit comprising:
an RC-based circuit for detecting the ESD event; and
a driver controlled by the RC-based circuit, for driving the gate and the substrate of the substrate-triggered MOS.

25. The power-rail ESD clamp circuit as claimed in claim 24, wherein the RC-based circuit includes a resistor and a capacitor, connected in series between the two power lines.

26. The ESD clamp circuit between power lines as claimed in claim 24, wherein the driver includes an inverter, having an output node coupled to the gate and the substrate of the substrate-triggered MOS.
